(19) United States
(12) Patent Application Publication
(10) Pub. No.: US 2023/0367040 A1
(43) Pub. Date: Nov. 16, 2023

(54) OPTICAL MULTILAYER STRUCTURE, METHOD OF MANUFACTURING THE SAME, AND WINDOW COVER FILM INCLUDING THE SAME

(71) Applicant: SK INNOVATION CO., LTD., Seoul (KR)

(72) Inventors: A Ran HWANG, Daejeon (KR); Keon Hyeok KO, Daejeon (KR); Byoung Sun KO, Daejeon (KR); Hye Jin KIM, Daejeon (KR); Jeong Min CHOI, Daejeon (KR)

(21) Appl. No.: 18/315,505

(22) Filed: May 11, 2023

(30) Foreign Application Priority Data
May 11, 2022 (KR) 10-2022-0057661

(51) Int. Cl. G02B 1/14; G09F 9/30

(52) U.S. Cl. CPC G02B 1/14; G09F 9/301

(57) ABSTRACT

An optical multilayer structure comprising a substrate layer; and a hard coating layer formed on one surface of the substrate layer, wherein the optical multilayer structure has a water contact angle of an outermost layer in accordance with ASTM D5964 of 105° or less. The optical multilayer structure according to one embodiment has improved adhesion with a different kind of film due to high surface energy of an outermost layer to have both excellent durability and excellent wear resistance, and thus, may be usefully applied to a window cover film or a flexible display panel.

### CROSS-REFERENCE TO RELATED APPLICATIONS

This application claims priority to Korean Patent Application No. 10-2022-0057661, filed on May 11, 2022. The entire contents of the above-listed application are hereby incorporated by reference for all purpose.

### TECHNICAL FIELD

The following disclosure relates to an optical multilayer structure, a method of manufacturing the same, and a window cover film and a flexible display panel including the same.

### BACKGROUND

Recently, thin display devices using flat panel display devices such as liquid crystal display devices or organic light emitting diode display devices are drawing a lot of attention. In particular, these thin displays are implemented in the form of a touch screen panel, and are widely used in various smart devices characterized by their portability including various wearable devices as well as smart phones and tablet PCs.

These portable touch screen panel-based displays are provided with a window cover for display protection on a display panel in order to protect the display panel from scratches or external impact. A method of forming a film on the surface of an optical film used as a window cover film, which uses a hydrophobic material having fluorine and silicon elements exhibiting contamination resistance and wear resistance is known, but in this case, durability is deteriorated by decreased adhesion between different kinds of films due to low surface energy.

### SUMMARY

An embodiment of the present disclosure is directed to providing an optical multilayer structure having a water contact angle of an outermost layer of about 105° or less and excellent durability.

Another embodiment of the present disclosure is directed to providing a window cover film including the optical multilayer structure.

Still another embodiment of the present disclosure is directed to providing a flexible display panel including the window cover film.

In one general aspect, an optical multilayer structure includes: a substrate layer and a hard coating layer formed on one surface of the substrate layer, wherein the optical multilayer structure has a water contact angle of an outermost layer in accordance with ASTM D5964 or 1050 or more.

In another general aspect, a window cover film includes the optical multilayer structure according to the embodiment.

In still another general aspect, a flexible display panel includes the window cover film according to the embodiment.

In still another general aspect, an optical multilayer structure includes: a substrate layer and a hard coating layer formed on one surface of the substrate layer, and an anti-fingerprint layer formed on the hard coating layer,
wherein a water contact angle of the anti-fingerprint layer in accordance with ASTM D5964 is of between 85° and 105° or less, and wherein the hard coating layer is a cured alkoxysilane having an epoxy group.

Other features and aspects will be apparent from the following detailed description, the drawings, and the claims.

### DETAILED DESCRIPTION OF EMBODIMENTS

The embodiments described in the present specification may be modified in many different forms, and the technology according to one embodiment is not limited to the embodiments set forth herein. In addition, the embodiments of the present disclosure are provided so that they will be described in more detail to a person with ordinary skill in the art. Furthermore, throughout the specification, unless explicitly described to the contrary, “comprising” any constituent elements will be understood to imply further inclusion of other constituent elements.

The numerical range used in the present specification includes all values within the range including the lower limit and the upper limit, increments logically derived in a form and span in a defined range, all double limited values, and all possible combinations of the upper limit and the lower limit in the numerical range defined in different forms. As an example, when it is defined that a content of a composition is 10% to 80% or 20% to 50%, it should be interpreted that a numerical range of 10% to 50% or 50% to 80% is also described in the specification of the present. Unless otherwise defined in the present specification, values which may be outside a numerical range due to experimental error or rounding of a value are also included in the defined numerical range.

Hereinafter, unless otherwise particularly defined in the present specification, “about” may be considered as a value within 30%, 25%, 20%, 15%, 10%, or 5% of a stated value.

Hereinafter, unless otherwise defined in the present specification, it will be understood that when a part such as a layer, a film, a thin film, a region, or a plate is referred to as being “on” or “above” another part, it may include not only the case of being “directly on” the other part but also the case of having an intervening part therebetween.

Hereinafter, unless otherwise particularly defined in the present specification, the term “A and/or B” may refer to an embodiment including both A and B or an embodiment selecting one of A and B.

Hereinafter, unless otherwise particularly defined in the present specification, a “polymer” refers to a molecule which has a relatively high molecular weight and the structure may include multiple repetition of a unit derived from a low molecular weight molecule. In one embodiment, the polymer may be an alternating copolymer, a block copolymer, a random copolymer, a branched copolymer, a crosslinked copolymer, or a copolymer including all of them (for example, a copolymer including more than one monomer). In another embodiment, the polymer may be a homopolymer (for example, a copolymer including one monomer).

Hereinafter, unless otherwise particularly defined, the term “flexible” may refer to warping, being bent, or being folded.

A film having a hydrophobic material including fluorine and silicon atoms formed on its surface in order to enhance contamination resistance, scratch resistance, and/or wear resistance has high water contact angle and wear resistance due to the low surface energy of the fluorine and silicon atoms. However, when a different kind of film is attached to the surface of the conventional film formed of fluorine and silicon atoms, adhesion is lowered due to the low surface energy to deteriorate durability.

The optical multilayer structure of one embodiment increases the surface energy of an outermost layer to implement a water contact angle to 1050 or less, thereby having excellent adhesion with a different kind of film and having significantly increased durability. Besides, since the optical multilayer structure of one embodiment has high wear resistance with a low water contact angle, excellent physical or mechanical properties to be used in a window cover film are secured.

One embodiment provides an optical multilayer structure including: a substrate layer, and
a hard coating layer (cured layer) formed on one surface of the substrate layer;
wherein the optical multilayer structure has a water contact angle of an outermost layer in accordance with ASTM D5964 or 105° or less.

The optical multilayer structure according to an embodiment is not particularly limited as long as it is implemented with the water contact angle of 105° or less. The water contact angle may be, for example, 90° to 105°, 950 to 1050, 960 to 1050, 980 to 1050, 990 to 1050, 1000 to 1050, or 1020 to 1050.

The optical multilayer structure according to an embodiment may implement high wear resistance with the low water contact angle of 105° or less. The optical multilayer structure according to an embodiment may have a water contact angle in accordance with ASTM D5964 of 85° to 105°, after applying a load of about 0.5 kg to a rubber stick (available from MINOAN, Inc. (Anyang city, Gyeonggi-do, Republic of Korea)) having a diameter of about 6 mm and rubbing the rubber stick about 300 times reciprocatingly over a distance of about 40 mm at a speed of about 40 rpm on the surface of the outermost layer. The range of the water contact angle after abrasion with a rubber stick is not necessarily limited to the above range, and may be, for example, 85° to 102°, 890 to 1050, 90° to 1050, 930 to 1050, 930 to 1020, 950 to 100°, 90° to 100°, or 95° to 99°. The optical multilayer structure according to an embodiment may increase the surface energy of the outermost layer to secure durability even in attachment/use of a different kind of film and also implement high wear resistance properties, and thus, may have excellent physical or mechanical properties.

The optical multilayer structure according to an embodiment may have a peel force of 5.0 gf/25 mm to 12.0 gf/25 mm, as measured at a peeling rate of about 300 mm/min using UTM available from INSTRON after fixing the outermost layer with 3M™ double-sided tape. The peel force is not necessarily limited to the range, and for example, may be 5.0 gf/25 mm to 10.0 gf/25 mm, 6.0 gf/25 mm to 10.0 gf/25 mm, 6.0 gf/25 mm to 9.5 gf/25 mm, 6.2 gf/25 mm to 9.5 gf/25 mm, 6.3 gf/25 mm to 9.5 gf/25 mm, 7.0 gf/25 mm to 9.0 gf/25 mm, 7.5 gf/25 mm to 8.5 gf/25 mm, 5.5 gf/25 mm to 8.5 gf/25 mm, or 5.9 to 7.9 gf/25 mm.

In an embodiment, the substrate layer may be prepared from, for example, polyester-based resins such as polyethylene terephthalate, polyethylene isophthalate, and polybutylene terephthalate; cellulose-based resins such as diacetyl cellulose and triacetyl cellulose; polycarbonate-based resins; acrylic resins such as polymethyl (meth)acrylate and polyethyl (meth)acrylate; styrene-based resins such as a polystyrene acrylonitrile-styrene copolymer; polyolefin-based resin such as polyethylene, polypropylene, polyolefin-based resin having a cyclo-based or norbornene structure, and ethylene propylene copolymer; polyimide-based resins; polyaramide-based resins; polyethersulfone-based resins; sulfone-based resins; and the like, and these resins may be used alone or in combination of two or more, but the present disclosure is not necessarily limited thereto. In an embodiment, the substrate layer may be excellent in transparency, mechanical strength, thermal stability, moisture shielding properties, isotropy, and the like.

In an embodiment, the substrate layer may be a polyimide-based substrate layer formed of a polyimide-based resin including a unit derived from a fluorine-based aromatic diamine, in which the polyimide-based resin may include both a polyimide resin and a polyamideimide resin.

In an embodiment, the polyimide-based substrate layer includes a polyamideimide resin including an aliphatic cyclic structure and a fluorine atom, and as a specific example, may be a polyimide-based substrate layer including a unit derived from a fluorine-based aromatic diamine, an aromatic dianhydride, and an aromatic diacid dichloride, and as a more specific example, may be a polyimide-based substrate layer further including a unit derived from a cycloaliphatic dianhydride, but is not necessarily limited thereto.

In an embodiment, the substrate layer does not cause a rainbow phenomenon or a mura phenomenon, has excellent optical properties, further lowers the haze of a window cover film, may further increase a total light transmittance, and may have better transparency.

In an embodiment, the thickness of the substrate layer is not particularly limited, and for example, may be 10 μm to 150 μm, 10 μm to 100, 20 μm to 80 μm, 30 μm to 70 μm, or 40 μm to 60 μm, but is not necessarily limited thereto.

In an embodiment, the hard coating layer may be formed on one or both surfaces of the substrate layer, thereby protecting the substrate layer from external physical and chemical damage.

In an embodiment, the hard coating layer may be formed by curing a composition for forming a hard coating layer, and also, may be a composite hard coating layer obtained by photocuring and then thermally curing the composition for forming a hard coating layer, but is not necessarily limited thereto.

In an embodiment, the hard coating layer may be formed by including a condensate of alkoxysilane having an epoxy group, and for example, the condensate of alkoxysilane having an epoxy group may be a siloxane resin including an epoxy group, but the present disclosure is not necessarily limited thereto. The condensate of alkoxysilane having an epoxy group may have excellent hardness and bending properties when cured.

The epoxy group may be any one or more selected from a cyclic epoxy group, an aliphatic epoxy group, and an aromatic epoxy group, and the siloxane resin may refer to a polymer compound in which a silicon atom and an oxygen atom form a covalent bond.

In an embodiment, the condensate of alkoxysilane having an epoxy group may be a silsesquioxane resin having an epoxy group, and specifically, a silsesquioxane resin in which a silicon atom is directly substituted with an epoxy group or a substituent of the silicon atom is substituted with an epoxy group, and more specifically, the condensate of alkoxysilane having an epoxy group may be a silsesquioxane resin substituted with 2-(3,4-epoxycyclohexyl)ethyl group, but is not necessarily limited thereto.

In an embodiment, the condensate of alkoxysilane having an epoxy group may have a weight average molecular weight of 1,000 g/mol to 20,000 g/mol, 1,000 g/mol to 18,000 g/mol, or 2,000 g/mol to 15,000 g/mol. When the weight average molecular weight is in the described range, flowability, coatability, curing reactivity, and the like of the composition for forming a hard coating layer may be further improved.

In an embodiment, the condensate of alkoxysilane having an epoxy group may include a repeating unit derived from an alkoxysilane compound represented by the following Chemical Formula x:

R^{x1}ₓₙSi(OR^{x2})₄₋ₓₙ [Chemical Formula x]
wherein R^{x1} is a straight-chain or branched-chain alkyl group having 1 to 6 carbon atoms substituted with an epoxycycloalkyl group having 3 to 6 carbon atoms or an oxiranyl group, in which the alkyl group may include an ether group; R^{x2} is a straight-chain or branched-chain alkyl group having 1 to 7 carbon atoms; and xn is an integer of 1 to 3.

The alkoxysilane compound represented by Chemical Formula x may be, for example, 2-(3,4-epoxycyclohexyl)ethyltrimethoxysilane, 2-(3,4-epoxycyclohexyl)ethyltriethoxysilane, 3-glycidoxypropyltrimethoxysilane, and the like and may be used alone or in combination of two or more, but is not necessarily limited thereto.

In an embodiment, the condensate of alkoxysilane having an epoxy group may be included at 20 parts by weight to 70 parts by weight or 20 parts by weight to 50 parts by weight with respect to 100 parts by weight of the composition for forming a hard coating layer, but is not necessarily limited thereof.

In an embodiment, the composition for forming a hard coating layer may have flowability and coatability, may be uniformly cured during the curing of the composition for forming a hard coating layer to allow effective prevention of physical defects such as cracks by overcuring, and may show excellent hardness.

In an embodiment, the hard coating layer may be formed by further including a crosslinking agent having a polyfunctional epoxy group. Herein, the crosslinking agent may include a compound having an alicyclic epoxy group, and for example, the crosslinking agent may include a compound having two 3,4-epoxycyclohexyl group bonded, but is not necessarily limited thereto. The crosslinking agent may have a structure and properties similar to the condensate of alkoxysilane having an epoxy group, and in this case, may promote crosslinking of the condensate of alkoxysilane having an epoxy group.

In an embodiment, the hard coating layer may have a thickness of 1 μm to 100 μm, 1 μm to 80 μm, 1 μm to 50 μm, 1 μm to 30 μm, 1 μm to 20 μm, or 1 μm to 10 μm, but is not necessarily limited thereto.

Hereinafter, a method of forming a hard coating layer will be described.

The hard coating layer is formed by preparing a composition for forming a hard coating layer, applying the composition on a substrate layer, and curing the composition.

In an embodiment, the composition for forming a hard coating layer may include a condensate of alkoxysilane having an epoxy group, in which the condensate of alkoxysilane having an epoxy group may be the same as those described above for the hard coating layer.

In an embodiment, the composition for forming a hard coating layer may further include a photoinitiator and a thermal initiator including a compound represented by the following Chemical Formula y:

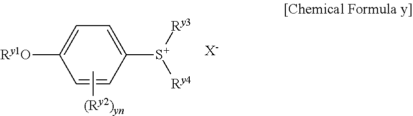

wherein R^{y1} is hydrogen, an alkoxycarbonyl group having 1 to 4 carbon atoms, an alkylcarbonyl group having 1 to 4 carbon atoms, or an arylcarbonyl group having 6 to 14 carbon atoms; R^{y2} is independently of each other hydrogen, a halogen, or an alkyl group having 1 to 4 carbon atoms; yn is 1 to 4, R^{y3} is an alkyl group having 1 to 4 carbon atoms or an aralkyl group having 7 to 15 carbon atoms which may be substituted with an alkyl group having 1 to 4 carbon atoms; R^{y4} is an alkyl group having 1 to 4 carbon atoms; and X is SbF₆, PF₆, AsF₆, BF₄, CF₃SO₃, N(CF₃SO₂)₂, or N(C₆F₅)₄.

The alkoxycarbonyl group has an alkoxy portion having 1 to 4 carbon atoms, and for example, may be a methoxycarbonyl group, an ethoxycarbonyl group, a propoxycarbonyl group, and the like.

The alkylcarbonyl group has an alkyl portion having 1 to 4 carbon atoms, and for example, may be an acetyl group, a propionyl group, and the like.

The arylcarbonyl group has an aryl portion having 6 to 14 carbon atoms, and for example, may be a benzoyl group, a 1-naphthylcarbonyl group, a 2-naphthylcarbonyl group, and the like.

An aralkyl group may be, for example, a benzyl group, a 2-phenylethyl group, a 1-naphthylmethyl group, a 2-naphthylmethyl group, and the like.

When the compound of Chemical Formula y is used as a thermal initiator, a cure half-life may be shortened and thermal curing may be rapidly performed even in low-temperature conditions, and thus, damage and deformation due to a long-term heat treatment under high-temperature conditions may be prevented.

The thermal initiator may promote the crosslinking reaction of the epoxy siloxane resin or the crosslinking agent described later when heat is applied to the composition for forming a hard coating layer. As the thermal initiator, a cationic thermal initiator may be used, but the present disclosure is not necessarily limited thereto.

In addition, by using photocuring using the photoinitiator in combination with the thermal curing using the thermal initiator, the curing degree, the hardness, the flexibility, and the like of the hard coating layer may be improved. For example, the composition for forming a hard coating layer is applied to a substrate or the like and irradiated with ultraviolet rays (photocuring) to at least partially cure the composition, and then heat is further applied (thermal curing), thereby performing substantially complete curing.

The composition for forming a hard coating layer may be semi-cured or partially cured by the photocuring, and the semi-cured or partially cured composition for forming a hard coating layer may be substantially completely cured by the thermal curing.

For example, when the composition for forming a hard coating layer is cured only by the photocuring, a curing time may be excessively extended or curing may not be completely performed in some parts. However, when the photocuring is followed by the thermal curing, the portion which is not cured by the photocuring may be substantially completely cured by the thermal curing, and the curing time may be also reduced.

In addition, generally, a portion which has been already appropriately cured is provided with excessive energy due to an increased curing time (for example, an increased light exposure time), which may cause overcuring. When the overcuring proceeds, the hard coating layer loses flexibility or results in mechanical defects such as curls or cracks may occur. However, the photocuring and the thermal curing are used in combination, the composition for forming a hard coating layer may be substantially completely cured within a short time and the hardness of the hard coating layer may be further increase while the flexibility of the hard coating layer is maintained.

Though the method of first photocuring and then further thermally curing the composition for forming a hard coating layer has been described above, the sequence of the photocuring and the thermal curing is not particularly limited thereto. That is, in some embodiments, the thermal curing may be first performed and then the photocuring may be performed.

In an embodiment, the thermal initiator may be included at 0.1 parts by weight to 20 parts by weight or 1 part by weight to 20 parts by weight with respect to 100 parts by weight of the condensate of alkoxysilane having an epoxy group, but is not necessarily limited thereto.

In addition, for example, the thermal initiator may be included at 0.01 parts by weight to 15 parts by weight, 0.1 parts by weight to 15 parts by weight, or 0.3 parts by weight to 10 parts by weight with respect to a total of 100 parts by weight of the composition for forming a hard coating layer, but is not necessarily limited thereto.

In an embodiment, the photoinitiator may include a photocationic initiator. The photocationic initiator may initiate polymerization of the epoxy siloxane resin and an epoxy-based monomer.

As the photo-cationic initiator, an onium salt and/or an organic metal salt, and the like may be used, and for example, a diaryliodonium salt, a triarylsulfonium salt, an aryldiazonium salt, an iron-arene composite, and the like may be used alone or in combination of two or more, but the present disclosure is not necessarily limited thereto.

The content of the photoinitiator is not particularly limited, but for example, the photoinitiator may be included at 0.1 parts by weight to 15 parts by weight or 1 part by weight to 15 parts by weight with respect to 100 parts by weight of the condensate of alkoxysilane having an epoxy group, but is not necessarily limited thereto.

In addition, for example, the photoinitiator may be included at 0.01 parts by weight to 10 parts by weight, 0.1 parts by weight to 10 parts by weight, or 0.3 parts by weight to 5 parts by weight with respect to a total of 100 parts by weight of the composition for forming a hard coating layer, but is not necessarily limited thereto.

In an embodiment, the composition for forming a hard coating layer may further include a crosslinking agent. For example, the crosslinking agent may form crosslinks with the condensate of alkoxysilane having an epoxy group to solidify the composition for forming a hard coating layer and increase the hardness of the hard coating layer.

In an embodiment, the crosslinking agent may include a compound having an alicyclic epoxy group. For example, the crosslinking agent may include a compound in which two 3,4-epoxycyclohexyl groups are connected to each other, but is not necessarily limited thereto. The crosslinking agent may have a structure and properties similar to the condensate of alkoxysilane having an epoxy group, and in this case, the crosslinking agent may promote the crosslinks of the condensate of alkoxysilane having an epoxy group and maintain an appropriate viscosity of the composition.

In an embodiment, the crosslinking agent may be included at 5 parts by weight to 150 parts by weight with respect to 100 parts by weight of the condensate of alkoxysilane having an epoxy group, but is not necessarily limited thereto. The viscosity of the composition may be maintained in an appropriate range by the crosslinking agent, and applicability and curing reactivity may be more improved.

In addition, for example, the crosslinking agent may be included at 1 part by weight to 30 parts by weight or 5 parts by weight to 20 parts by weight with respect to a total of 100 parts by weight of the composition for forming a hard coating layer, but is not necessarily limited thereto.

In an embodiment, the composition for forming a hard coating layer may further include a thermal curing agent.

The thermal curing agent may include amine-based, imidazole-based, acid anhydride-based, and amide-based thermal curing agents, and the like, and these may be used alone or in combination of two or more, but the present disclosure is not necessarily limited thereto.

In an embodiment, the thermal curing agent may be included at 5 parts by weight to 30 parts by weight with respect to 100 parts by weight of the condensate of alkoxysilane having an epoxy group, but is not necessarily limited thereto. The hardness efficiency of the composition for forming a hard coating layer may be further improved by the thermal curing agent to form a hard coating layer having better hardness.

In an embodiment, the composition for forming a hard coating layer may further include a solvent. The solvent is not particularly limited and may be a solvent known in the art.

A non-limiting example of the solvent may include alcohol-based solvents (such as methanol, ethanol, isopropanol, butanol, methyl cellosolve, and ethyl cellosolve), ketone-based solvents (such as methyl ethyl ketone, methyl butyl ketone, methyl isobutyl ketone, diethyl ketone, dipropyl ketone, and cyclohexanone), hexane-based solvents (such as hexane, heptane, and octane), benzene-based solvents (such as benzene, toluene, and xylene), and the like. These may be used alone or in combination of two or more.

The content of the solvent is not particularly limited, and for example, may be 10 parts by weight to 200 parts by weight with respect to 100 parts by weight of the condensate of alkoxysilane having an epoxy group. When the solvent is used, the composition for forming a hard coating layer may secure an appropriate level of viscosity, and thus, workability during formation of the hard coating layer may be better. In addition, it is easy to adjust the thickness of the hard coating layer and a solvent drying time is reduced, whereby a more rapid process speed may be secured.

In an embodiment, the solvent may be included in a residual amount excluding the amount of the remaining components in the total weight of a predetermined entire composition. For example, when the total weight of the predetermined entire composition is 100 g and the sum of the weights of the components other than the solvent is 70 g, 30 g of the solvent may be included, but the present disclosure is not necessarily limited thereto.

In an embodiment, the composition for forming a hard coating layer may further include an inorganic filler. The inorganic filler may further increase the hardness of the hard coating layer.

The inorganic filler is not particularly limited, and an example thereof may include metal oxides such as silica, alumina, and titanium oxide; hydroxides such as aluminum hydroxide, magnesium hydroxide, and potassium hydroxide; metal particles such as gold, silver, bronze, nickel, and alloys thereof; conductive particles such as carbon, carbon nanotubes, and fullerene; glass; ceramic; and the like, or in terms of compatibility with other components of the composition for forming a hard coating layer, silica may be used, and these may be used alone or in combination of two or more, but the present disclosure is not necessarily limited thereto.

In an embodiment, the composition for forming a hard coating layer may further include a lubricant. The lubricant may further improve winding efficiency, blocking resistance, wear resistance, scratch resistance, and the like.

The kind of lubricant is not particularly limited, and for example, waxes such as polyethylene wax, paraffin wax, synthetic wax, or montan wax; synthetic resins such as silicon-based resins and fluorine-based resins; and the like may be used, and these may be used alone or in combination of two or more, but the present disclosure is not necessarily limited thereto.

Besides, the composition for forming a hard coating layer may further include additives such as, for example, an antioxidant, a UV absorber, a photostabilizer, a thermal polymerization inhibitor, a leveling agent, a surfactant, a lubricant, and an antifouling agent.

The optical multilayer structure according to an embodiment may have improved antifouling properties by further including an anti-fingerprint layer on the hard coating layer. In an embodiment, the anti-fingerprint layer may be formed from a composition including the compound represented by the following Chemical Formula 1:

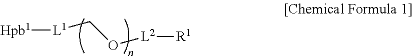

wherein
Hpb¹ is a hydrophobic group including a fluorine-based polymer;
L¹ is a linker including a siloxane-based compound;
L² is a linker including one or more selected from C₁₋₁₀ alkylene, and C₅₋₈ cycloalkylene substituted with C₁₋₁₀ alkyl, a carbamate group, and a carbamide group;
R¹ is a reactive group including an alkoxy siloxane-based compound; and
n is an integer of 1 to 30.

In an embodiment, the fluorine-based polymer included in Hpb¹ may be, for example, perfluoropolyether (PFPE) or a derivative thereof. The perfluoropolyether may be used without limitation as a hydrophobic group of the compound represented by Chemical Formula 1 according to an embodiment as long as it is a chain compound including carbon, oxygen, and fluorine atoms. In an embodiment, the anti-fingerprint layer is formed from a composition including a compound including a fluorine-based polymer, so that a fluorine functional group is oriented on an upper layer of the surface of the anti-fingerprint layer to further improve antifouling properties, water repellency, and/or oil repellency. The perfluoropolyether may include a perfluorinated repeating unit selected from, for example, —O— (CF₂CF₂O)ₐ—(CF₂O)_{b}—CF₂—, —(OCF₂CF₂)_{c}—O—CF₂—, —(CF(CF₃)CF₂O)_{d}—CF₂CF₂—, —(CeF₂ₑ)—, —(C_{f}F_{2f}O)—, —(CF(Z))—, —(CF(Z)O)—, —(CF(Z)C_{g}F_{2g}O)—, —(CₕF₂ₕCF(Z)O)—, —(CFᵢCF(Z)O)—, and combinations thereof, or the like, may be linear, branched, cyclic, combinations thereof, or the like, or may be saturated or unsaturated, but is not necessarily limited thereto. Herein, a to i may be an integer of 1 to 200, 1 to 150, 1 to 100, or 1 to 50, Z may be any one selected from a fluorine group, a perfluoroalkyl group, a perfluoroether group, a nitrogen-containing perfluoroalkyl group, a perfluoropolyether group, a perfluoroalkoxy group, and the like, and all of them may be linear, branched, or cyclic, but are not necessarily limited thereto.

In addition, in an embodiment, the fluorine-based polymer may also include a derivative of perfluoropolyether substituted with a substituent which may be easily derived by a person skilled in the art disclosed in the present specification or including a linker (for example, a linker including a carbonyl group, such as an oxo group, an ester group, and an amide group).

In an embodiment, L² is a hydrophilic linker, and for example, may include C₁₋₈ alkylene, C₁₋₅ alkylene, C₃₋₈ alkylene, or C₃₋₅ alkylene; C₅₋₈ cycloalkylene substituted with C₁₋₈ alkyl, C₁₋₅ alkyl, C₁₋₃ alkyl, C₃₋₈ alkyl, or C₃₋₅ alkyl; or C₅₋₆ cycloalkylene substituted with C₁₋₈ alkyl, C₁₋₅ alkyl, C₁₋₃ alkyl, C₃₋₈ alkyl, or C₃₋₅ alkyl, —OC(═O)N—, and/or —NC(═O)N—.

In an embodiment, L² may include one or more, two or more, three or more, or two or three of the listed substituents.

Herein, the alkyl includes both straight-chain alkyl and branched-chain alkyl. In addition, the substituted cycloalkyl includes all of the cases in which one or two or more substituents are mono-substituted, di-substituted, or mono- to penta-substituted.

In an embodiment, in the cycloalkyl, one ring may be included, or two or more rings may be connected via a fused junction (the bridgehead carbons are directly connected) a bridged bicyclic junction (the bridgehead carbons are connected by bridges containing at least one common carbon), or a spiro junction (two rings connected to a single common carbon). For example, the cycloalkyl may be cyclopentyl, cyclohexyl, cycloheptyl, or

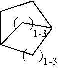

which is mono- to penta-substituted with 1 to 5 straight-chain or branched-chain C₁₋₁₀ alkyl, C₁₋₈ alkyl, C₁₋₅ alkyl, or C₁₋₃ alkyl.

In an embodiment, the reactive group R¹ may refer to a substituent which is hydrolysable or bonded to a hard coating layer. Specifically, for example, the reactive group may include an alkoxysilane-based compound. The hydrolysable reactive group may form a chemical bond with a compound included in a substrate by a hydrolysis group or a condensation group, thereby further increasing interlayer binding force.

In an embodiment, n may be an integer of 1 to 25, 1 to 20, 3 to 20, or 5 to 20, but is not necessarily limited thereto. The compound represented by Chemical Formula 1 according to an embodiment includes a hydrophilic group including a —(CH₂—O)ₙ— (polyethylene glycol, PEG) repeating unit, thereby lowering the water contact angle of the anti-fingerprint layer formed from the composition including the compound represented by Chemical Formula 1.

In an embodiment, the compound represented by Chemical Formula 1 may be a compound represented by the following Chemical Formula 1A:

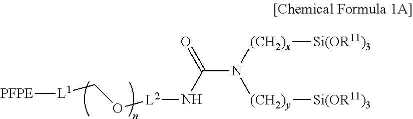

wherein
PFPE is perfluoropolyether or a derivative thereof;
x and y are independently of each other an integer of 1 to 10; and
R¹¹ is independently of each other C₁₋₁₀ alkyl.
PFPE, L¹, L², and n are as defined in Chemical Formula 1.

In an embodiment, x and y may be independently of each other an integer of 1 to 8, 1 to 6, 1 to 5, or 1 to 3. In addition, in an embodiment, R¹¹ may be independently of each other straight-chain or branched-chain C₁₋₁₀ alkyl, C₁₋₈ alkyl, C₁₋₅ alkyl, or C₁₋₃ alkyl.

The anti-fingerprint layer according to an embodiment is formed from a composition including a compound having a hydrophobic group including a fluorine atom or a silicon atom to which a hydrophilic group (compound including polyalkylene oxide) is introduced, thereby lowering the water contact angle and increasing the surface energy of the anti-fingerprint layer and/or the optical multilayer structure including the anti-fingerprint layer to improve adhesion.

In an embodiment, the anti-fingerprint layer may be formed from a composition further including a compound represented by the following Chemical Formula 2 with the compound represented by Chemical Formula 1:

R²-L³-Hpb²-L⁴-R³ [Chemical Formula 2]
wherein
Hpb² is a hydrophobic group including a fluorine-based polymer;
L³ and L⁴ are independently of each other a linker including a straight-chain or branched-chain hydrocarbon group(hydrocarbylene); and
R² and R³ are independently of each other a reactive group including an alkoxy siloxane-based compound.

In an embodiment, the fluorine-based polymer included in Hpb² may be, for example, perfluoropolyether (PFPE) or a derivative thereof. The definition of Chemical Formula 1 may be applied to the perfluoropolyether.

L³ and L⁴ may be independently of each other a linker including straight-chain or branched-chain C₁₋₁₀ alkylene, C₁₋₈ alkylene, C₁₋₆ alkylene, C₁₋₅ alkylene, or C₁₋₃ alkylene, and L³ and L⁴ may further include a linker which may be easily derived by a person skilled in the art and disclosed in the present specification (for example, a hydrophilic linker, or as a linker including a carbonyl group, an oxy group, an ester group, an amide group, a carbamate group, a carbamide group, or the like).

In an embodiment, the compound represented by Chemical Formula 2 may be a compound represented by the following Chemical Formula 2A:

(R²¹O)₃Si-L³-PFPE-L⁴-Si(OR³¹)₃ [Chemical Formula 2A]
wherein
PFPE is perfluoropolyether or a derivative thereof; and
R²¹ and R³¹ are independently of each other C₁₋₁₀ alkyl;
PFPE, L³, and L⁴ are as defined in Chemical Formula 2.

In an embodiment, R²¹ and R²² may be independently of each other straight-chain or branched-chain C₁₋₁₀ alkyl, C₁₋₈ alkyl, C₁₋₅ alkyl, or C₁₋₃ alkyl.

In an embodiment, the anti-fingerprint layer and/or the optical multilayer structure formed using a composition including the compound represented by Chemical Formula 1 and the compound represented by Chemical Formula 2 may have a water contact angle in accordance with ASTM D5964 of 98° to 115°, 100° to 110°, or 100° to 105°, but is not necessarily limited thereto.

In an embodiment, the water contact angle in accordance with ASTM D5964 may be 85° to 105°, 90° to 105°, or 95° to 105°, after applying a load of 0.5 kg to a rubber stick (available from Minoan) having a diameter of 6 mm and rubbing the rubber stick 300 times reciprocatingly over a distance of 40 mm at a speed of 40 rpm on the surface of the optical multilayer structure or the anti-fingerprint layer included in the optical multilayer structure, but is not necessarily limited thereto.

When the anti-fingerprint layer according to an embodiment is formed from a composition including both the compound represented by Chemical Formula 1 and the compound represented by Chemical Formula 2, a mass ratio between the compound represented by Chemical Formula 1 and the compound represented by Chemical Formula 2 may be 7:3 to 9.8:0.2. The mass ratio is not necessarily limited to the range, and for example, may be 7.5:2.5 to 9.8:0.2, 8:2 to 9.8:0.2, 8.5:1.5 to 9.8:0.2, 8.5:1.5 to 9.5:0.5, or 9:1.

In an embodiment, the anti-fingerprint layer and/or the optical multilayer structure formed from a composition including the compound represented by Chemical Formula 1 and the compound represented by Chemical Formula 2 may have a peel force of 5.0 gf/25 mm to 10.0 gf/25 mm, 5.0 gf/25 mm to 9.0 gf/25 mm, 5.0 gf/25 mm to 8.5 gf/25 mm, 5.5 gf/25 mm to 9.0 gf/25 mm, 6.0 gf/25 mm to 10.0 gf/25 mm, 6.0 gf/25 mm to 9.0 gf/25 mm, or 6.0 gf/25 mm to 8.0 gf/25 mm, as measured at a peeling rate of 300 mm/min using UTM available from INSTRON after fixation with 3M™ double-sided tape, but is not necessarily limited thereto.

Since a method of preparing a compound including a fluorine-based polymer and a siloxane-based compound is already been publicly known, the compound represented by Chemical Formula 1 and the compound represented by Chemical Formula 2 according to an embodiment may be easily prepared and carried out using an already known preparation method by a person skilled in the art, or using a method obtained by properly modifying a known preparation method with a commonly known method by a person skilled in the art. For example, the compounds may be prepared by reacting a unit such as a fluorine-based polymer having an unsaturated bond at one end or both ends (for example, perfluoropolyether), siloxane, and polyethylene glycol (PEG).

In an embodiment, the compound represented by Chemical Formula 1 may be prepared by reacting a fluorine-based polymer substituted with an epoxy group at the end (Hpb¹), siloxane to which a PEG unit is bonded (including L¹), a hydrophilic group including L², and an alkoxyl siloxane-based compound, as monomers. In an embodiment, the compound represented by Chemical Formula 2 may be prepared by reacting a fluorine-based polymer substituted with a hydroxyl group at the end (Hpb²) and a compound including a hydrocarbon group (L², L³) to which a siloxane-based compound (R², R³) is bonded as monomers. In an embodiment, for example, each monomer may be connected by forming a bond by a —NCO group at the end with an —OH group and/or an —NH group.

In an embodiment, the anti-fingerprint layer may be formed by applying a composition for forming an anti-fingerprint layer on an adhesion promoting layer and drying & curing the composition. In an embodiment, the anti-fingerprint layer may be formed by thermally curing the composition for forming an anti-fingerprint layer. Drying may be performed at 50° C. to 150° C., 60° C. to 120° C., 60° C. to 100° C., or 70° C. to 90° C. for 1 minute to 30 minutes, 1 minute to 20 minutes, 1 minute to 15 minutes, or 1 minute to 10 minutes. The thermal curing may be performed at 100° C. to 250° C., 120° C. to 220° C., 150° C. to 200° C., or 160° C. to 180° C. for 1 minute to 30 minutes, 5 minutes to 20 minutes, or 8 minutes to 15 minutes.

The anti-fingerprint layer according to an embodiment is formed from a composition including a compound having a hydrophobic group including a fluorine atom or a silicon atom to which a hydrophilic group (compound including polyalkylene oxide) is introduced, thereby increasing the surface energy of the anti-fingerprint layer and/or the optical multilayer structure to improve adhesion. In addition, a reactive group is introduced to both ends of the compound having a hydrophobic group including a fluorine atom, thereby increasing reaction sites with a coated substrate to increase binding force to improve wear resistance. Therefore, the anti-fingerprint layer and/or the optical multilayer structure according to an embodiment have/has excellent rubber stick wear resistance and scratch resistance while having high surface energy, and thus, may have a lowered defect occurrence rate and a high durability degree even when it is used as a real product.

In an embodiment, the composition for forming an anti-fingerprint layer may include a solvent, the solvent may include any one or a combination of two or more selected from, for example, hexafluoroxylene, hydrofluorocarbon, hydrofluoroether, and the like, and a commercialized example of the solvent may include NOVEC™ HFE-7500, 7200, 7100 available from 3M™, Vertrel® XF available from DuPont™, ZEORORA® H available from Nippon Zeon, and the like, but these are only non-limiting examples, and the present disclosure is not necessarily limited thereto.

In an embodiment, the anti-fingerprint layer may have a thickness of 1 nm to 100 nm, 1 nm to 80 nm, or 10 nm to 60 nm, but is not necessarily limited thereto.

The optical multilayer structure according to an embodiment may include: a substrate layer; a hard coating layer formed on one surface of the substrate layer; and an anti-fingerprint layer formed from a composition including the compound represented by Chemical Formula 1.

Herein, “formed on a hard coating layer” includes the case of being formed above but not adjacent to a hard coating layer as well as the case of being formed on one surface of a hard coating layer.

The anti-fingerprint layer which may be included in the optical multilayer structure according to an embodiment is prepared from a composition including a compound having a hydrophilic group (hydrophilic moiety) grafted between a reactive group (reaction site) having a silicon atom and a hydrophobic group (hydrophobic moiety) including a fluorine atom, and the adhesion of the film is increased by increasing the surface energy of the anti-fingerprint layer and/or the optical multilayer structure including the anti-fingerprint layer, thereby providing an optical multilayer structure having significantly improved durability, and a window cover film and/or a flexible display panel including the optical multilayer structure.

The optical multilayer structure according to an embodiment may further include an adhesion promoting layer. In an embodiment, the adhesion promoting layer may be formed on the hard coating layer, and for example, the adhesion promoting layer may be formed in contact with the upper surface of the hard coating layer.

In an embodiment, the adhesion promoting layer may be formed from a composition including an alkoxysilane-based compound having one or two or more functional groups. The alkoxysilane-based compound having one or two or more functional groups is an alkoxysilane-based compound substituted with one or two or more functional groups, and for example, may be an alkoxysilane-based compound in which a silicon atom is directly substituted with the functional group or a substituent substituted on a silicon atom (for example, an alkyl group) or the like is substituted with the functional group. That is to say, it may be a compound in which an alkyl group substituted with one or two or more functional groups is connected to a silicon atom, but is not necessarily limited thereto.

In an embodiment, the functional group may be an organofunctional group, and for example, the organofunctional group may be any one selected from a carboxyl group, an epoxy group, a mercapto group, an isocyanate group, an amino group, and the like or a combination thereof, but is not necessarily limited thereto.

Since an alkoxysilane-based compound having an organofunctional group has both an alkoxysilane group which reacts with an inorganic material and an organofunctional group forming a chemical bond with an organic material in the molecule, it has an excellent ability to combine an organic material and an inorganic material and may decrease the surface energy of an organic material to further increase adhesive strength with an inorganic material. In addition, the alkoxysilane-based compound having an organofunctional group may increase compatibility with other resins.

Therefore, when the alkoxysilane-based compound having one or two or more functional groups included in the adhesion promoting layer has both the organofunctional group and an alkoxysilane group, the alkoxysilane-based compound included in the alkoxysilane-based compound may form a chemical bond with both the condensate of alkoxysilane having an epoxy group of the hard coating layer and a fluorine-containing alkoxysiloxane-based compound included in the anti-fingerprint layer. In addition, when the adhesion promoting layer is formed between the hard coating layer and the anti-fingerprint layer, a binding force between each layer is further significantly improved, so that each layer may be substantially integrated.

In an embodiment, the alkoxysilane-based compound having one or two or more functional groups included in the adhesion promoting layer and the fluorine-containing alkoxysiloxene-based compound included in the anti-fingerprint layer may form a chemical bond by a hydrolysis reaction between hydrolysable reactive groups, a condensation reaction, and the like, and in this case, a binding force between the adhesion promoting layer and the anti-fingerprint layer may be further improved, but these are only non-limiting examples, and the present disclosure is not necessarily limited thereto. In an embodiment, when the adhesion promoting layer is formed between the hard coating layer and the anti-fingerprint layer, the optical multilayer structure according to an embodiment and a window cover film including the optical multilayer structure may have a significantly improved binding force between each layer, may have significantly improved wear resistance, scratch resistance, fingerprint wipeability, and the like, and also, may implement significantly improved surface properties such as a sense of touch and slip properties.

In an embodiment, a commercialized example of the alkoxysilane-based compound having one or two or more functional groups may include KBM-402, KBM-603, KBM-903, KBM-802, and the like available from SHIN-ETSU, but which are only a non-limiting example, and the present disclosure is not necessarily limited thereto.

In an embodiment, the adhesion promoting layer may have a thickness of 1 nm to 300 nm, 1 nm to 200 nm, 1 nm to 100 nm, or 10 nm to 50 nm, but is not necessarily limited thereto.

Hereinafter, a method of forming an adhesion promoting layer will be described.

The adhesion promoting layer is formed by preparing a composition for forming an adhesion promoting layer, applying the composition on a hard coating layer, and drying the composition.

In an embodiment, the composition for forming an adhesion promoting layer may include an alkoxysilane-based compound having one or two or more functional groups, in which the alkoxysilane-based compound having one or two or more functional groups may be the same as those described above for the adhesion promoting layer.

In an embodiment, the composition for forming an adhesion promoting layer may further include a solvent. The solvent is not particularly limited and may be a solvent known in the art. A non-limiting example of the solvent may include alcohol-based solvents (such as methanol, ethanol, isopropanol, butanol, methyl cellosolve, and ethyl cellosolve), ketone-based solvents (such as methyl ethyl ketone, methyl butyl ketone, methyl isobutyl ketone, diethyl ketone, dipropyl ketone, and cyclohexanone), and the like. These may be used alone or in combination of two or more.

In an embodiment, the application may be performed by a die coater, an air knife, a reverse roll, a spray, a blade, casting, gravure, spin coating, and the like, but is not necessarily limited thereto.

The optical multilayer structure according to an embodiment may include: a substrate layer; a hard coating layer formed on one surface of the substrate layer; an adhesion promoting layer which is formed on the hard coating layer and is formed from a composition including an alkoxysilane-based compound having one or more functional groups; and an anti-fingerprint layer which is formed on the adhesion promoting layer and is formed from a composition including the compound represented by Chemical Formula 1.

One embodiment provides a method of manufacturing an optical multilayer structure including the following operations, respectively, or in combination.

The method of manufacturing an optical multilayer structure according to an embodiment may include (A) applying a composition for forming a hard coating layer on one surface of the substrate layer and curing the composition to form a hard coating layer.

The method of manufacturing an optical multilayer structure according to an embodiment may include: (A) applying a composition for forming a hard coating layer on one surface of the substrate layer and curing the composition to form a hard coating layer; and (B) applying a composition for forming an adhesion promoting layer (for example, a composition for forming an adhesion promoting layer including an alkoxysilane-based compound having one or more functional groups) on the hard coating layer and drying the composition to form an adhesion promoting layer.

The method of manufacturing an optical multilayer structure according to an embodiment may include: (A) applying a composition for forming a hard coating layer on one surface of the substrate layer and curing the composition to form a hard coating layer; and (B) applying a composition for forming an adhesion promoting layer (for example, a composition for forming an adhesion promoting layer including an alkoxysilane-based compound having one or more functional groups) on the hard coating layer and drying the composition to form an adhesion promoting layer; and (C) applying a composition for forming an anti-fingerprint layer (for example, a composition for forming an anti-fingerprint layer including the compound represented by Chemical Formula 1 and/or the compound represented by Chemical Formula 2) on the adhesion promoting layer and curing the composition to form an anti-fingerprint layer.

One embodiment provides a window cover film including the optical multilayer structure according to an embodiment.

In an embodiment, the window cover film may further include any one or more functional coating layers selected from an antistatic layer, an anti-fingerprint layer, an anti-scratch layer, a low refractive index layer, a low reflection layer, a water repellent layer, an antireflection layer, and a shock absorption layer, and is not necessarily limited thereto.

The window cover film according to an embodiment includes any window cover film having improved adhesion with high wear resistance and scratch resistance by including the anti-fingerprint layer according to an embodiment, and thus, the substrate layer, the hard coating layer, the adhesion promoting layer, the antistatic layer, the anti-fingerprint layer, the anti-scratch layer, the low refractive layer, the low reflection layer, the water repellent layer, the antireflection layer, and/or the shock absorption layer is/are not necessarily specified into a specific material.

One embodiment provides a flexible display panel or a flexible display device including the window cover film according to the embodiment.

Since the anti-fingerprint layer according to an embodiment has excellent durability as well as wear resistance and scratch resistance, it may be effectively applied to a window cover film and/or a flexible display panel.

The window cover film may be used as an outermost window substrate of a flexible display device. The flexible display device may be various image display devices such as a common liquid crystal display device, an electroluminescent display device, a plasma display device, and a field emission display device.

One embodiment provides an optical multilayer structure comprising: a substrate layer and a hard coating layer formed on one surface of the substrate layer, and an anti-fingerprint layer formed on the hard coating layer, wherein a water contact angle of the anti-fingerprint layer in accordance with ASTM D5964 is of between 85° and 105° or less, and wherein the hard coating layer is a cured alkoxysilane having an epoxy group.

Since the description of the optical multilayer structure can be applied in the same manner as described above, it will be omitted below.

Hereinafter, the examples and the experimental examples will be illustrated in detail. However, since the examples and the experimental examples described below only illustrate a part of one embodiment, the implemented embodiment is not limited to the examples and the experimental examples.

<Test Method>

1. Water Contact Angle

A contact angle was measured using a water contact angle meter (Kruss, DSA-100) in accordance with the specification of ASTM D5964.

2. Water Contact Angle after Abrasion with Rubber Stick

A film was cut into a size of 7 cm×8 cm and fixed to a scratch tester (available from Kipae E&T Co., Ltd.), and a rubber stick having a diameter of 6 mm (MINOANM Inc.) was mounted and fixed to a cylindrical rubber holder. The rubber stick was rubbed 300 times back and forth on the surface of a film (anti-fingerprint layer) with the settings of a moving distance of 40 mm (i.e., the distance between the two opposite ends of the reciprocating rubbing movement being 40 mm), at a moving speed of 40 rpm, and a load of 0.5 kg, and then the water contact angle of the worn surface was measured in accordance with the method of measuring a water contact angle described above.

3. Scratch Resistance

A film was cut into a size of 10 cm×12 cm and fixed to a scratch tester (Kipae E&T Co., Ltd.), and steel wool (#0000, BON STAR™) was mounted and fixed to a square jig having a length of 20 mm. The steel wool was rubbed 1500 times reciprocatingly on the surface of a film (anti-fingerprint layer) with the settings of a moving distance of 40 mm, a moving speed of 40 rpm, and a load of 1.0 kg, and whether there were flaws (scratches) on the surface was visually observed. After observation, when there was no damage (5 or fewer scratches of 2 cm or less), it was determined as being good quality denoted as “OK” in the table 1, and when there was damage, it was determined as not good and denoted with “NG” in the table 1.

4. Peel Force

A film having a protection film (anti-fingerprint layer) attached thereon was cut into a size of 25×150 cm and was fixed to a glass plate with 3M™ double-sided tape, and a peeling protection film was fixed to the jig of a Universal Testing Machine (UTM) model 3365 of INSTRON, a US company. An average peel force (gf/25 mm) at a point of 20 mm to 80 mm of the film when peeling at a rate of 300 mm/min at an angle of 1800 was calculated.

### Example 1

1-1. Preparation of Composition for Forming Hard Coating Layer

2-(3,4-epoxycyclohexyl)ethyltrimethoxysilane (ECTMS, TCI) and water were mixed at a ratio of 24.64 g:2.70 g (0.1 mol:0.15 mol) to prepare a reaction solution, which was added to a 250 mL 2-neck flask. 0.1 mL of a tetramethylammonium hydroxide catalyst (Sigma-Aldrich®) and 100 mL of tetrahydrofuran (Sigma-Aldrich®) were added to the mixture and stirred at 25° C. for 36 hours. Thereafter, layer separation was performed, a product layer was extracted with methylene chloride (Sigma-Aldrich®), moisture was removed from the extract with magnesium sulfate (Sigma-Aldrich®), and the solvent was dried under vacuum to obtain an epoxy siloxane-based resin. The weight average molecular weight of the epoxy siloxane-based resin was measured using gel permeation chromatography (GPC), and the result was 2,500 g/mol.

30 g of the epoxy siloxane-based resin as prepared above, 10 g of (3′,4′-epoxycyclohexyl)methyl 3,4-epoxycyclohexane carboxylate and 5 g of bis[(3,4-epoxycyclohexyl)methyl] adipate as a crosslinking agent, 0.5 g of (4-methylphenyl) [4-(2-methylpropyl)phenyl]iodoniumhexafluorophosphate as a photoinitiator, 0.1 g of 4-acetoxyphenyldimethylsulfonium hexafluoroantimonate as a thermal initiator, and 54.5 g of methylethyl ketone were mixed, thereby preparing a composition for forming a hard coating layer.

1-2. Preparation of Composition for Forming Adhesion Promoting Layer

An alkoxysilane-based compound containing an epoxy group and an alkoxysilane group (Shin-etsu, KBM-402) was diluted with an ethanol solution so that a solid content was 0.2 wt %, thereby preparing a composition for forming adhesion promoting layer.

1-3. Preparation of Composition for Forming Anti-Fingerprint Layer

CF₃—(OCF₂CF₂)₄—Si(CH₃)₂OSi(CH₃)₂—CH₂ [CH₂CH₂ (OCH₂CH₂)₈—CH₂CH₂—OCONH—C₆H₁₂NHCON]—[CH₂CH₂CH₂—Si(OCH₃)₃]₂ was diluted in a fluorine-based solvent (3M™, Novec 7200) so that a solid content was 0.1 wt %, thereby preparing a composition for forming an anti-fingerprint layer.

1-4. Preparation of Substrate Layer

In a reactor under a nitrogen atmosphere, terephthaloyl dichloride (TPC) and 2,2′-bis(trifluoromethyl)-benzidine (TFMB) were added to a mixed solution of dichloromethane and pyridine, and stirring was performed at 25° C. for 2 hours under a nitrogen atmosphere. At this time, TPC and TFMB were added at a mole ratio of 3:4 and the solid content was adjusted to 10 wt % to perform polymerization. Thereafter, the product was precipitated in an excessive amount of methanol and filtered to obtain a solid content, which was dried under vacuum at 50° C. for 6 hours or more to obtain an oligomer, and the prepared oligomer had a formula weight (FW) of 1670 g/mol.

N,N-dimethylacetamide (DMAc) as a solvent, 100 mol of the oligomer, and 28.6 mol of 2,2′-bis(trifluoromethyl)-benzidine (TFMB) were added to the reactor and sufficient stirring was performed. Thereafter, 64.3 mol of cyclobutanetetracarboxylic dianhydride (CBDA) and 64.3 mol of 4,4′-hexafluoroisopropylidene diphthalic anhydride (6FDA) were added to the reactor, sufficient stirring was performed, and polymerization was performed at 40° C. for 10 hours. At this time, the solid content of the reaction solution was 20 wt %. Subsequently, each of pyridine and acetic anhydride was added to the reaction solution sequentially at 2.5-fold to the total content of dianhydride, and stirring was performed at 60° C. for 12 hours.

After the polymerization was completed, the polymerization solution was precipitated in an excessive amount of methanol and filtered to obtain a solid content, which was dried under vacuum at 50° C. for 6 hours or more, thereby obtaining polyamideimide powder. The powder was diluted and dissolved at 20 wt % in DMAc to prepare a composition for forming a substrate layer.

The composition for forming a substrate layer was applied on a substrate (glass substrate) using an applicator, dried at 90° C. for 25 minutes, cooled to room temperature, heated to 280° C. for 30 minutes, and heated for 30 minutes to manufacture a substrate layer. At this time, the thickness of the substrate layer was 50 μm.

1-5. Preparation of Hard Coating Layer

The composition for forming a hard coating layer prepared as described above was applied on one surface of the substrate layer manufactured above using a meyer bar, and dried at a temperature of 60° C. for 3 minutes. Thereafter, UV was irradiated at 1 kJ/cm² using a high pressure metal lamp to prepare a hard coating layer. At this time, the thickness of the hard coating layer was 5 μm.

1-6. Preparation of Adhesion Promoting Layer

The hard coating layer prepared above was corona-treated four times (Enercon, CTW-0212) at 250 V, and the composition for forming an adhesion promoting layer was applied using a meyer bar #10 and dried at a temperature of 25° C. for 3 minutes to prepare an adhesion promoting layer. At this time, the thickness of the adhesion promoting layer was 32 μm.

1-7. Preparation of Anti-Fingerprint Layer

The composition for forming an anti-fingerprint layer prepared above was applied on the adhesion promoting layer using a meyer bar #7, dried at 80° C. for 5 minutes, and thermally cured at 170° C. for 10 minutes to form an anti-fingerprint layer and an optical multilayer structure. At this time, the thickness of the anti-fingerprint layer was 32 μm.

### Example 2

An optical multilayer structure was manufactured in the same manner as in the preparation step of the composition for forming an anti-fingerprint layer of Example 1, except that CF₃—(OCF₂CF₂)₄—Si(CH₃)₂OSi(CH₃)₂—CH₂ [CH₂CH₂ (OCH₂CH₂)₁₀—CH₂CH₂—OCONH—C₆H₁₂NHCON]—[CH₂CH₂CH₂—Si(OCH₃)₃]₂ was used instead of CF₃—(OCF₂CF₂)₄—Si(CH₃)₂OSi(CH₃)₂—CH₂ [CH₂CH₂ (OCH₂CH₂)₈—CH₂CH₂—OCONH—C₆H₁₂NHCON]—[CH₂CH₂CH₂—Si(OCH₃)₃]₂.

### Example 3

An optical multilayer structure was manufactured in the same manner as in the preparation step of the composition for forming an anti-fingerprint layer of Example 1, except that CF₃—(OCF₂CF₂)₄—Si(CH₃)₂OSi(CH₃)₂—CH₂ [CH₂CH₂ (OCH₂CH₂)₁₂—CH₂CH₂—OCONH—C₆H₁₂NHCON]—[CH₂CH₂CH₂—Si(OCH₃)₃]₂ was used instead of CF₃—(OCF₂CF₂)₄—Si(CH₃)₂OSi(CH₃)₂—CH₂ [CH₂CH₂ (OCH₂CH₂)₈—CH₂CH₂—OCONH—C₆H₁₂NHCON]—[CH₂CH₂CH₂—Si(OCH₃)₃]₂.

### Example 4

An optical multilayer structure was manufactured in the same manner as in the preparation step of the composition for forming an anti-fingerprint layer of Example 1, except that CF₃—(OCF₂CF₂)₄—Si(CH₃)₂OSi(CH₃)₂—CH₂ [CH₂CH₂ (OCH₂CH₂)₁₂—CH₂CH₂—OCONH—C₆H₁₂NHCON]—[CH₂CH₂CH₂—Si(OCH₃)₃]₂ and Si(OCH₃)₃—C₆H₁₂—NHCOO—CF₂—(OCF₂CF₂)₄—OCONH—C₆H₁₂—Si(OCH₃)₃ were mixed at a mass ratio of 9:1 and diluted in a fluorine-based solvent (3M™, Novec™ 7200) so that a solid content was 0.1 wt % to prepare a composition for forming an anti-fingerprint layer.

### Example 5

An optical multilayer structure was manufactured in the same manner as in Example 4, except that the mass ratio was 8:2.

### Example 6

An optical multilayer structure was manufactured in the same manner as in Example 4, except that the mass ratio was 8:2.

### Comparative Example 1

KY-1901 available from Shin-etsu was purchased and prepared.

### Experimental Examples

Optical multilayer structures manufactured in Examples 1 to 6 were used to measure the physical properties according to 1 to 4 of <Test method>, which are shown in the following Table 1.

TABLE 1

| | | Water contact | | |
|---|---|---|---|---|
| | Initial water | angle after | | |
| | contact angle | abrasion with | Scratch | Peel force |
| | (°) | rubber stick (°) | resistance | (gf/25 mm) |
| Example 1 | 101 | 89 | OK | 8.6 |
| Example 2 | 100 | 87 | OK | 9.0 |
| Example 3 | 98 | 85 | OK | 9.2 |
| Example 4 | 102 | 95 | OK | 7.9 |
| Example 5 | 103 | 97 | OK | 6.3 |
| Example 6 | 104 | 99 | OK | 5.9 |
| Comparative | 115 | 99 | OK | 4.2 |
| Example 1 | | | | |

As confirmed in Table 1 above, the optical multilayer structures according to the examples were manufactured from the composition including a compound obtained by introducing a hydrophilic group (compound including polyalkylene oxide) to a compound having a hydrophobic group including a fluorine atom and a silicon atom, thereby increasing the surface energy of the anti-fingerprint layer to improve adhesion excellently, and having excellent scratch resistance and wear resistance even with the high surface energy.

The present disclosure relates to an optical multilayer structure including a substrate layer and a hard coating layer and having a water contact angle of an outermost layer of 1050 or less. The optical multilayer structure according to one embodiment has improved adhesion with a different kind of film due to high surface energy of an outermost layer to have both excellent durability and excellent wear resistance, and thus, may be usefully applied to a window cover film or a flexible display panel.

Hereinabove, one embodiment has been described in detail by the preferred examples and experimental examples. However, the scope of implemented embodiment is not limited to the specific examples, and should be construed by the appended claims.

What is claimed is:

1. An optical multilayer structure comprising:
a substrate layer; and
a hard coating layer formed on one surface of the substrate layer,
wherein the optical multilayer structure has a water contact angle of an outermost layer in accordance with ASTM D5964 of 1050 or less.

2. The optical multilayer structure of claim 1, wherein the water contact angle in accordance with ASTM D5964 is 85° to 105°, after applying a load of 0.5 kg to a rubber stick from Minoan having a diameter of 6 mm and rubbing the rubber stick 300 times reciprocatingly over a distance of 40 mm at a speed of about 40 rpm on a surface of the outermost layer.

3. The optical multilayer structure of claim 1, wherein the optical multilayer structure has a peel force of 5.0 gf/25 mm to 12.0 gf/25 mm, as measured at a peeling rate of 300 mm/min using UTM available from INSTRON after fixing the outermost layer with 3M™ double-sided tape.

4. The optical multilayer structure of claim 1, wherein the hard coating layer includes a condensate of silane having an epoxy group.

5. The optical multilayer structure of claim 1, wherein the substrate layer includes a polyimide-based film including a unit derived from a fluorine-based aromatic diamine.

6. The optical multilayer structure of claim 1, wherein the substrate layer includes a polyimide-based film including a unit derived from a fluorine-based aromatic diamine, a unit derived from an aromatic dianhydride, and a unit derived from an aromatic diacid dichloride.

7. The optical multilayer structure of claim 1, further comprising: an anti-fingerprint layer formed on the hard coating layer.

8. The optical multilayer structure of claim 7, wherein the anti-fingerprint layer is formed from a composition including a compound represented by the following Chemical Formula 1: 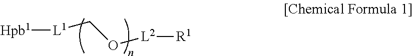
wherein
Hpb¹ is a hydrophobic group including a fluorine-based polymer;
L¹ is a linker including a siloxane-based compound;
L² is a linker including one or more selected from C₁₋₁₀ alkylene, and C₅₋₈ cycloalkylene substituted with C₁₋₁₀ alkyl, a carbamate group, and a carbamide group;
R¹ is a reactive group including an alkoxy siloxane-based compound; and
n is an integer of 1 to 30.

9. The optical multilayer structure of claim 8, wherein the fluorine-based polymer included in Hpb¹ is perfluoropolyether (PFPE) or a derivative thereof.

10. The optical multilayer structure of claim 8, wherein L² is a linker including one or more selected from C₁₋₈ alkylene, and C₅₋₆ cycloalkylene substituted with C₁₋₅ alkyl, a carbamate group, and a carbamide group.

11. The optical multilayer structure of claim 8, wherein the compound represented by Chemical Formula 1 is a compound represented by the following Chemical Formula 1A: 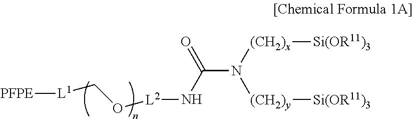
wherein
PFPE is perfluoropolyether or a derivative thereof;
x and y are independently of each other an integer of 1 to 10; and
R¹¹ is independently of each other C₁₋₁₀ alkyl.

12. The optical multilayer structure of claim 8, wherein the anti-fingerprint layer is formed from a composition further including a compound represented by the following Chemical Formula 2:
R²-L³-Hpb²-L⁴-R³ [Chemical Formula 2]
wherein
Hpb² is a hydrophobic group including a fluorine-based polymer;
L³ and L⁴ are independently of each other a linker including a straight-chain or branched-chain hydrocarbon group; and
R² and R³ are independently of each other a reactive group including an alkoxy siloxane-based compound.

13. The optical multilayer structure of claim 12, wherein the fluorine-based polymer included in Hpb² is perfluoropolyether or a derivative thereof.

14. The optical multilayer structure of claim 12, wherein the compound represented by Chemical Formula 2 is a compound represented by the following Chemical Formula 2A:
(R²¹O)₃Si-L³-PFPE-L⁴-Si(OR³¹)₃ [Chemical Formula 2A]
wherein
PFPE is perfluoropolyether or a derivative thereof; and
R²¹ and R³¹ are independently of each other C₁₋₁₀ alkyl.

15. The optical multilayer structure of claim 12, wherein the anti-fingerprint layer is formed from a composition including the compound represented by Chemical Formula 1 and the compound represented by Chemical Formula 2 at a mass ratio of 7:3 to 9.8:0.2.

16. A window cover film comprising the optical multilayer structure of claim 1.

17. A flexible display panel comprising the window cover film of claim 16.

18. An optical multilayer structure comprising:
a substrate layer and
a hard coating layer formed on one surface of the substrate layer, and
an anti-fingerprint layer formed on the hard coating layer,
wherein a water contact angle of the anti-fingerprint layer in accordance with ASTM D5964 is of between 85° and 105° or less, and
wherein the hard coating layer is a cured alkoxysilane having an epoxy group.
